(19) United States
(12) Patent Application Publication
(10) Pub. No.: US 2026/0343919 A1
(43) Pub. Date: Oct. 29, 2026

(54) PSEUDO CFET STRUCTURES AND THE METHODS OF FORMING THE SAME

(71) Applicant: Taiwan Semiconductor Manufacturing Company, Ltd., Hsinchu (TW)

(72) Inventors: Zhi-Chang Lin, Zhubei (TW); Yu-Tien Shen, Tainan (TW); Chih-Pin Lin, Hsinchu (TW); Ting-Yun Wu, Taipei (TW)

(21) Appl. No.: 19/721,783

(22) Filed: Jun. 26, 2026

Related U.S. Application Data
(63) Continuation of application No. 19/005,406, filed on Dec. 30, 2024.
(60) Provisional application No. 63/699,715, filed on Sep. 26, 2024.

(51) Int. Cl. H10D 30/01; H10B 10/00; H10D 30/00; H10D 30/67; H10D 62/10; H10D 64/01; H10D 64/23; H10D 84/01; H10D 84/85

(52) U.S. Cl. CPC H10D 30/0191; H10B 10/12; H10D 30/502; H10D 30/6735; H10D 30/6757; H10D 62/121; H10D 64/017; H10D 64/251; H10D 84/0167; H10D 84/017; H10D 84/0186; H10D 84/851

(57) ABSTRACT

A method includes forming a first multilayer stack in a first device region, forming a first gate stack over the first multilayer stack, forming a second multilayer stack in a second device region, forming a second gate stack over the second multilayer stack, etching the first multilayer stack to form a first source/drain recess, and etching the second multilayer stack to form a second source/drain recess. The method further includes forming a hard mask in the second source/drain recess, and forming a lower source/drain region in the first source/drain recess. After the lower source/drain region is formed, the hard mask is removed from the second source/drain recess. A first upper source/drain region and a second upper source/drain region are formed in the first source/drain recess and the second source/drain recess, respectively.

### PRIORITY CLAIM AND CROSS-REFERENCE

This application is a continuation of U.S. patent application Ser. No. 19/005,406 filed on Dec. 30, 2024, which application claims the benefit of the provisionally filed U.S. Patent Application No. 63/699,715, filed on Sep. 26, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIG. 2 through FIGS. 13A and 13B are views of intermediate stages in the formation of CFETs in accordance with some embodiments.

FIGS. 14A and 14B illustrate a CFET structure that may be used for forming a part of a Static Random-Access Memory (SRAM) cell in accordance with some embodiments.

FIG. 15 illustrates a schematic circuit diagram of a SRAM cell in accordance with some embodiments.

FIG. 16 illustrates a flow chart for forming CFETs and pseudo CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

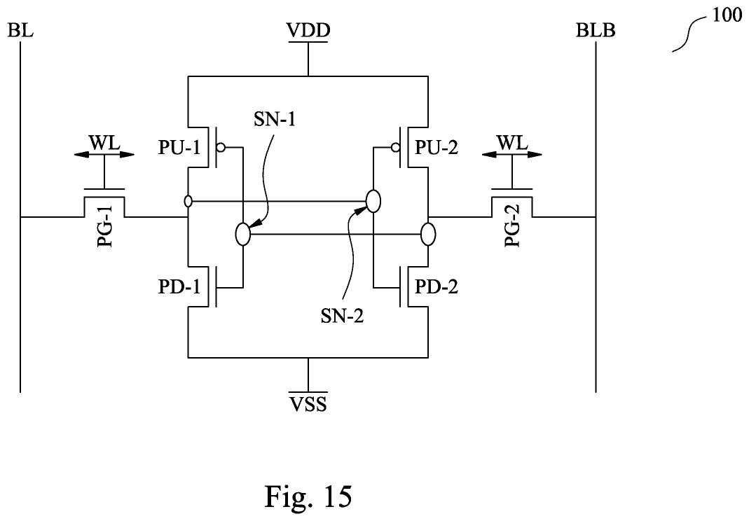

A Complementary Field-Effect Transistor (CFET), a pseudo-CFET, and the method of forming the same are provided. The pseudo-CFET has the structure similar to the structure of the CFET, and lacks one of the FETs such as a lower FET. In accordance with some embodiments, the CFET and the pseudo-CFET form a part of a Static Random-Access Memory (SRAM) cell (such as the SRAM cell 100 as shown in FIG. 15).

It is appreciated that while in the example embodiments, PFETs are lower FETs in the CFETs, the PFETs may also be formed as the upper FETs in accordance with alternative embodiments. Also, in the example illustrated embodiments, the pseudo-CFET lacks the lower FET and has the upper FETs. The concept of the process may also be applied to form a pseudo-CFET that lacks the upper FET and has the lower FET. The CFET and the pseudo-CFET, while being discussed as forming SRAM cells in some example embodiments, may be used in any other circuits in which there is more PFETs than NFETs, or more NFETs than PFETs. Throughout the description, the terms “FET” and “transistor” are used interchangeably.

FIG. 15 illustrates a circuit diagram of SRAM cell 100 in accordance with some embodiments. SRAM cell 100 includes pull-up transistors PU-1 and PU-2, which are PFETs. SRAM cell 100 further includes pull-down transistors PD-1 and PD-2 and pass-gate transistors PG-1 and PG-2, which are NFETs. The gates of pass-gate transistors PG-1 and PG-2 are connected to and controlled by word-line WL that determines whether SRAM cell 100 is selected or not.

A latch formed of pull-up transistors PU-1 and PU-2 and pull-down transistors PD-1 and PD-2 is capable of storing a bit, wherein the complementary values of the bit are stored in storage nodes SN-1 and SN-2. The stored bit can be written into or read from SRAM cell 100 through complementary bit lines including bit-line (BL) and bit-line bar (BLB).

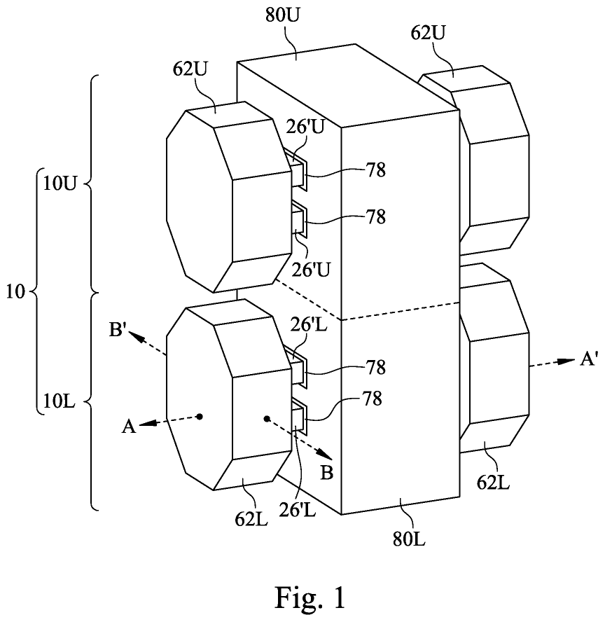

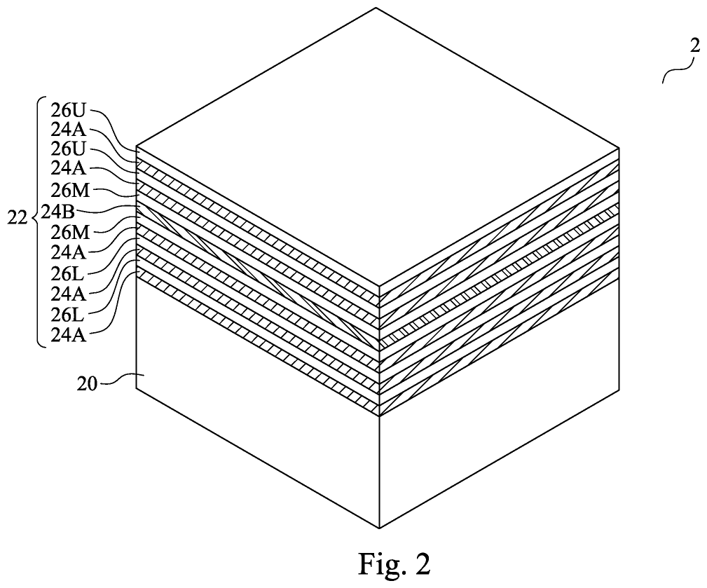

In accordance with some embodiments, the PFETs and the NFETs of SRAM cell 100 may be implemented using CFETs, which may have the structure as shown in FIG. 1. The SRAM cell 100 may be implemented through the processes as provided in the processes as shown in FIG. 2 through FIGS. 13A and 13B. It is appreciated that CFETs may have PFETs and NFETs in pairs. The SRAM cell 100, however, may have the number of PFETs different from the number of NFETs, such as four PFETs and two NFETs as shown in FIG. 15, and hence the PFETs and NFETs are not in pairs. The embodiments of the present disclosure provide the methods and the structures for implementing the un-paired PFETs and NFETs.

FIG. 1 illustrates an example of CFETs 10 (including FETs (transistors) 10U and 10L) in accordance with some embodiments, which has the structure that can be used for implementing the un-paired PFETs and NFETs such as the SRAM cell 100. FIG. 1 is a three-dimensional view, wherein some features of the CFETs are omitted for illustration clarity.

The CFETs include multiple vertically stacked FETs. For example, a CFET may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Source/drain region(s) may refer to a source or a drain, individually or collectively dependent upon the context. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26′ of a CFET and in a direction of, for example, a current flow between the source/drain regions 62 of the CFET. Cross-section B-B′ is a vertical cross-section that is perpendicular to cross-section A-A′ and along a longitudinal axis of a gate electrode 80 of the CFET. Subsequent figures may refer to these reference cross-sections for clarity.

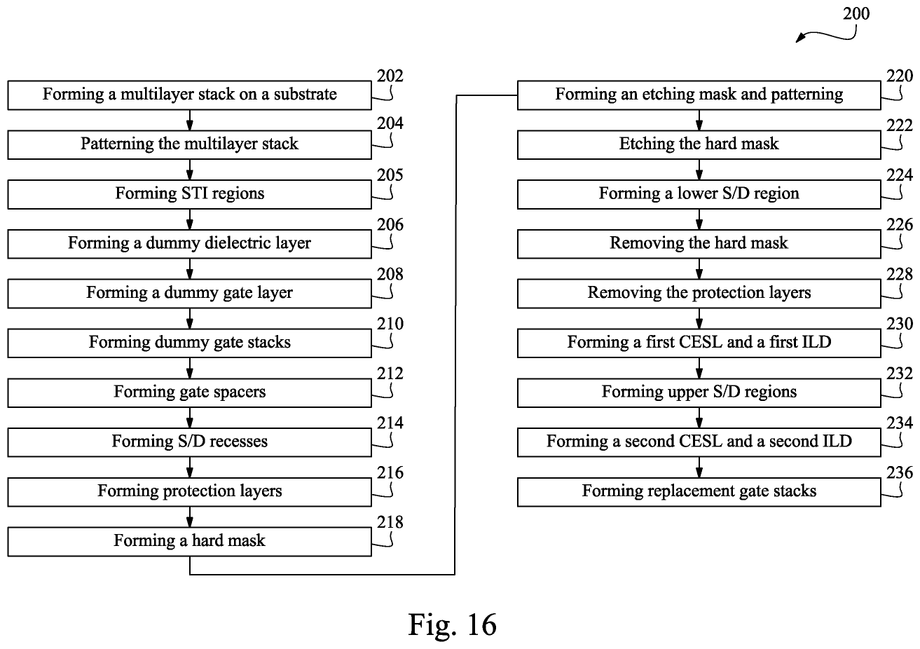

FIG. 2 through FIGS. 13A and 13B illustrate the cross-sectional views of intermediate stages in the formation of CFETs (as schematically represented in FIG. 1) in accordance with some embodiments. The corresponding processes are referred to as monolithic CFET (mCFET) formation processes. The corresponding processes are also reflected schematically in the process flow shown in FIG. 16.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor; or the like, or combinations thereof.

A multilayer stack 22 is formed over the substrate 20. The respective process is illustrated as process 202 in the process flow 200 as shown in FIG. 16. The multilayer stack 22 includes alternating dummy semiconductor layers 24 (including dummy semiconductor layers 24A and 24B) and semiconductor layers 26 (including lower semiconductor layers 26L and upper semiconductor layers 26U). Lower semiconductor layers 26L and upper semiconductor layers 26U are for forming a lower FET and an upper FET, respectively. There are also middle semiconductor layers 26M.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multilayer stack 22 includes six of the dummy semiconductor layers 24 and six of the semiconductor layers 26. It should be appreciated that the multilayer stack 22 may include any number of the dummy semiconductor layers 24 and the semiconductor layers 26. Each layer of the multilayer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

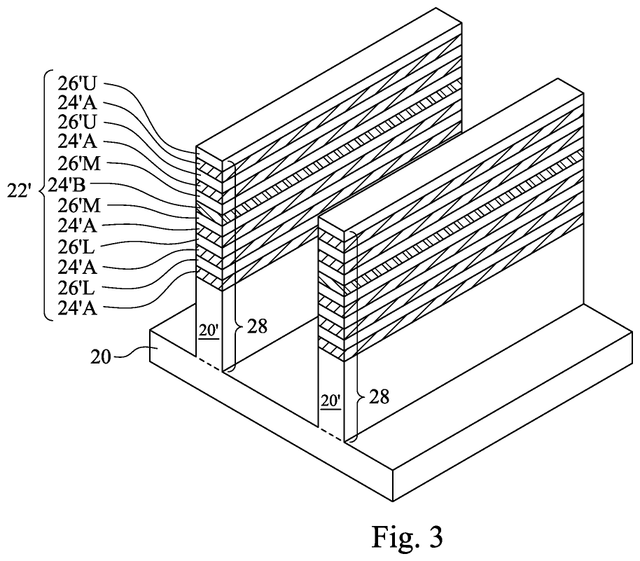

In FIG. 3, multilayer stack 22 and substrate 20 are patterned to form semiconductor strips 28. The respective process is illustrated as process 204 in the process flow 200 as shown in FIG. 16. Each of semiconductor strips 28 includes semiconductor strip 20′ (the portions of the original substrate 20) and multilayer stack 22′, which is the remaining portion of multilayer stack 22. The remaining portions 22′ of multilayers stack 22 are referred to as nanostructures hereinafter, which are referred to using the corresponding reference number followed by a “′” sign. Accordingly, multilayer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be individually and collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

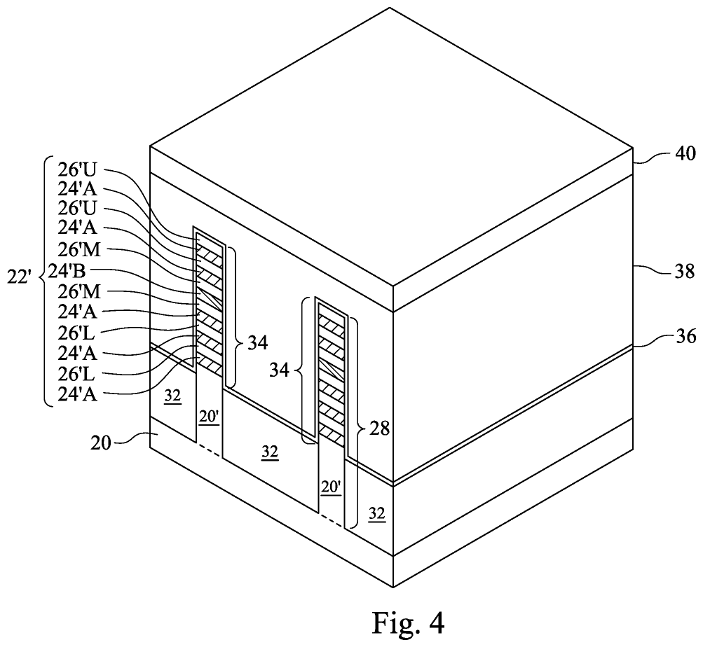

In FIG. 4, isolation regions 32 are formed over the substrate 20 and between adjacent semiconductor strips 28. The respective process is illustrated as process 205 in the process flow 200 as shown in FIG. 16. Isolation regions 32 may include a dielectric liner and a dielectric material over the dielectric liner. Isolation regions 32 are then recessed. Some upper portions of semiconductor strips 28 (including multilayer stacks 22′) protrude higher than the remaining isolation regions 32 to form protruding fins 34.

Dummy dielectric layer 36 is then formed on the protruding fins 34. The respective process is illustrated as process 206 in the process flow 200 as shown in FIG. 16. Dummy dielectric layer 36 may be formed of or comprise, for example, silicon oxide, silicon nitride, a combination thereof, or the like, and may be deposited or thermally grown according to acceptable techniques.

A dummy gate layer 38 is formed over the dummy dielectric layer 36. The respective process is illustrated as process 208 in the process flow 200 as shown in FIG. 16. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

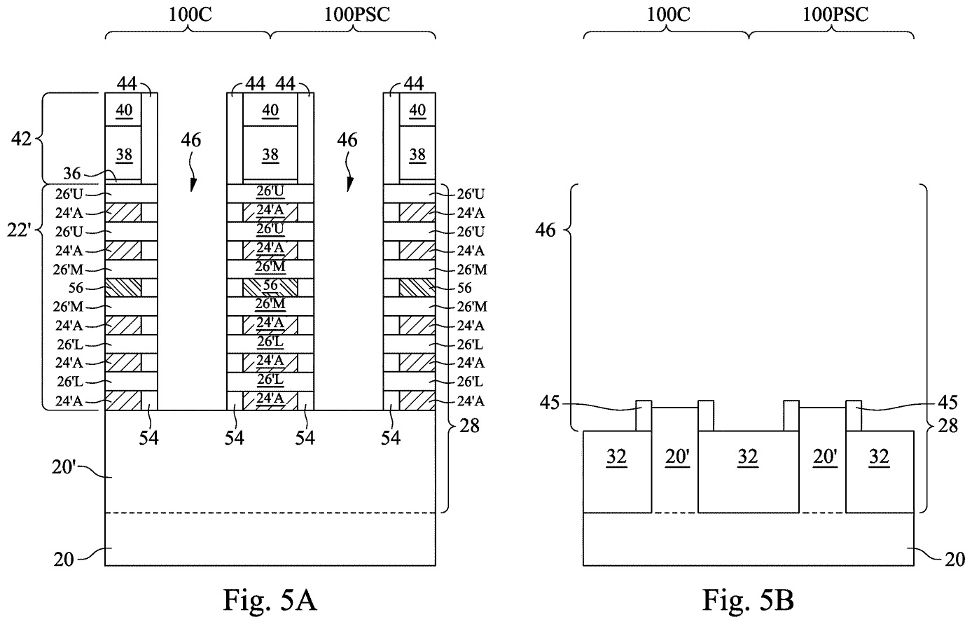

Next, the mask layer 40 may be patterned through photolithography and etching processes to form a mask, which is then used to etch and pattern dummy gate layer 38, and possibly dummy dielectric layer 36. A resulting structure is shown in FIGS. 5A and 5B. The remaining portions of mask layer 40, dummy gate layer 38, and dummy dielectric layer 36 form dummy gate stacks 42. The respective process is illustrated as process 210 in the process flow 200 as shown in FIG. 16.

In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the cross-sectional views along a similar cross-section as the vertical reference cross-section B-B′ in FIG. 1.

FIGS. 5A and 5B illustrate an initial structure for forming parts of an SRAM cell in accordance with some embodiments. The illustrated structure includes a part in CFET region 100C and a part in pseudo-CFET region 100PSC. In the CFET region 100C, a CFET including an NFET and a PFET are to be formed, which may form the pull-up transistor PU-1 or PU-2 and the pull-down transistor PD-1 or PD-2 (FIG. 15). In the pseudo-CFET region 100PSC, an NFET is to be formed as a part of a pseudo-CFET, which may form the pass-gate transistor PG-1 or PG-2 (FIG. 15). FIGS. 5A and 5B illustrate the vertical cross-sections A-A′ and B-B′, respectively, in FIG. 1. The structures in CFET region 100C and pseudo-CFET region 100PSC as shown in FIGS. 5A and 5B may be formed in common processes as shown in FIGS. 2 through 4.

It is appreciated that although in FIG. 5B, the CFET region 100C and pseudo-CFET region 100PSC are shown as being in the same plane for the easiness of viewing, the structures in CFET region 100C and pseudo-CFET region 100PSC as in FIG. 5B may actually be in different planes.

In FIG. 5A, gate spacers 44 are formed over the multilayer stacks 22′ and on exposed sidewalls of dummy gate stacks 42. The respective process is illustrated as process 212 in the process flow 200 as shown in FIG. 16. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. In FIG. 5B, fin spacers 45 are illustrated, which are formed from the same dielectric layer(s) for forming gate spacers 44.

Source/drain recesses 46 are formed in semiconductor strips 28 in both of CFET region 100C and pseudo-CFET region 100PSC. The respective process is illustrated as process 214 in the process flow 200 as shown in FIG. 16. The source/drain recesses 46 are formed through etching semiconductor strips 28, and may extend through the multilayer stacks 22′ and into the semiconductor strips 20′. The bottom surfaces of the source/drain recesses 46 may be at a level above, below, or level with the top surfaces of the isolation regions 32 (FIG. 5B). In the etching processes, the gate spacers 44 and the dummy gate stacks 42 mask some portions of the semiconductor strips 28. The source/drain recesses 46 may be formed in CFET region 100C and pseudo-CFET region 100PSC simultaneously in common processes.

Dummy nanostructures 24′A are then laterally recessed, and a dielectric material(s) is filled into the respective recesses to form inner spacers 54, which are dielectric spacers. Dielectric isolation layers 56 are also formed to replace the dummy nanostructures 24′B.

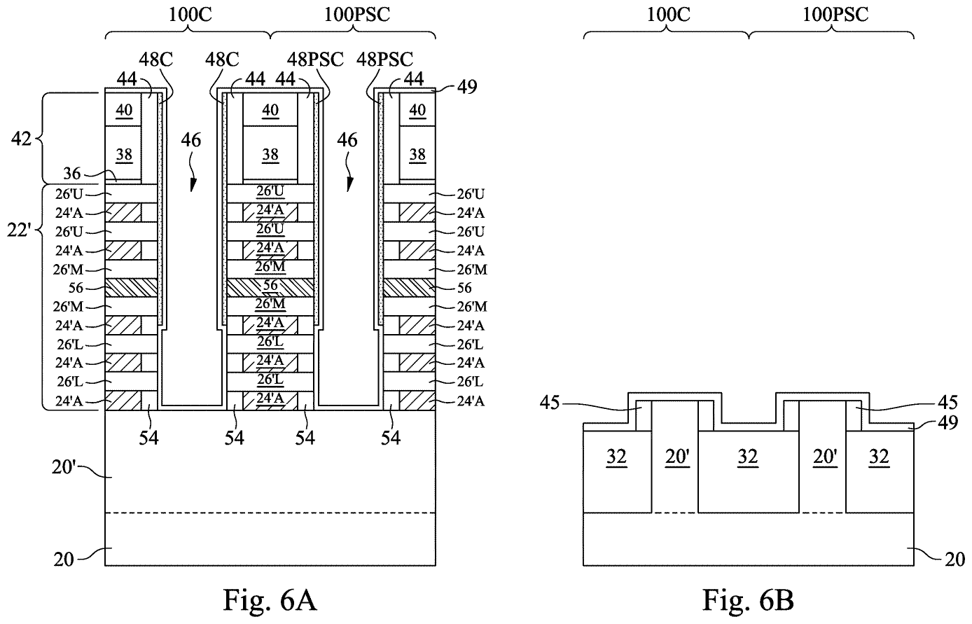

Referring to FIGS. 6A and 6B, protection liners 48C and 48PSC are formed. The respective process is illustrated as process 216 in the process flow 200 as shown in FIG. 16. Protection liners 48C and 48PSC may be formed in common processes or separate processes. Protection liners 48C and 48PSC may be formed of or comprise silicon oxide, silicon nitride, silicon oxynitride, silicon oxy-carbo-nitride, silicon carbide, or the like, or combinations thereof. The material of protection liners 48C and 48PSC are further different from the materials of the exposed features such as gate spacers 44, hard masks 40, inner spacers 54, and the like, so that in the subsequent removal of protection liners 48C and 48PSC, the exposed features are not damaged

In accordance with some embodiments, the formation of protection liners 48C and 48PSC may include depositing a sacrificial layer (not shown) filling the source/drain recesses 46, planarizing the sacrificial layer, and etching back the sacrificial layer. The top surface of the remaining sacrificial layer will be at the same level as the bottom end of the subsequently formed protection liners 48C and 48PSC. The sacrificial layer may comprise a photoresist or another polymer, which may be, or may not be photo sensitive.

A blanket protection layer is then deposited conformally, followed by an anisotropic etching process to remove the horizontal portions of the blanket protection layer, leaving the protection liners 48C and 48PSC as illustrated. The remaining portions of the sacrificial layer are then removed. In accordance with some embodiments, the bottom ends of the protection liners 48C and 48PSC are lower than the dielectric isolation layers 56, and higher than the bottom surface of the lower semiconductor nanostructures 26′L that is immediately underlying the middle semiconductor nanostructures 26′M.

In a subsequent process, as shown in FIGS. 6A and 6B, a hard mask 49 is formed in both of CFET region 100C and pseudo-CFET region 100PSC. The respective process is illustrated as process 218 in the process flow 200 as shown in FIG. 16. The formation process may include depositing a conformal dielectric layer into both of the CFET region 100C and pseudo-CFET region 100PSC. As shown in FIG. 6A, hard mask 49 masks the exposed sidewalls of semiconductor nanostructures 26′L and the surfaces of semiconductor strips 20′.

The formation process of hard mask 49 may include a conformal deposition process such as ALD, CVD, or the like. In accordance with some embodiments, the hard mask 49 is formed of a material that is different from the material of protection liners 48C and 48PSC. The material of the hard mask 49 may be (or may not be) selected from the same group of candidate materials for forming protection liners 48C and 48PSC. For example, the material of the hard mask 49 may comprise silicon oxide, silicon nitride, silicon oxynitride, silicon oxy-carbo-nitride, silicon carbide, or the like, or combinations thereof.

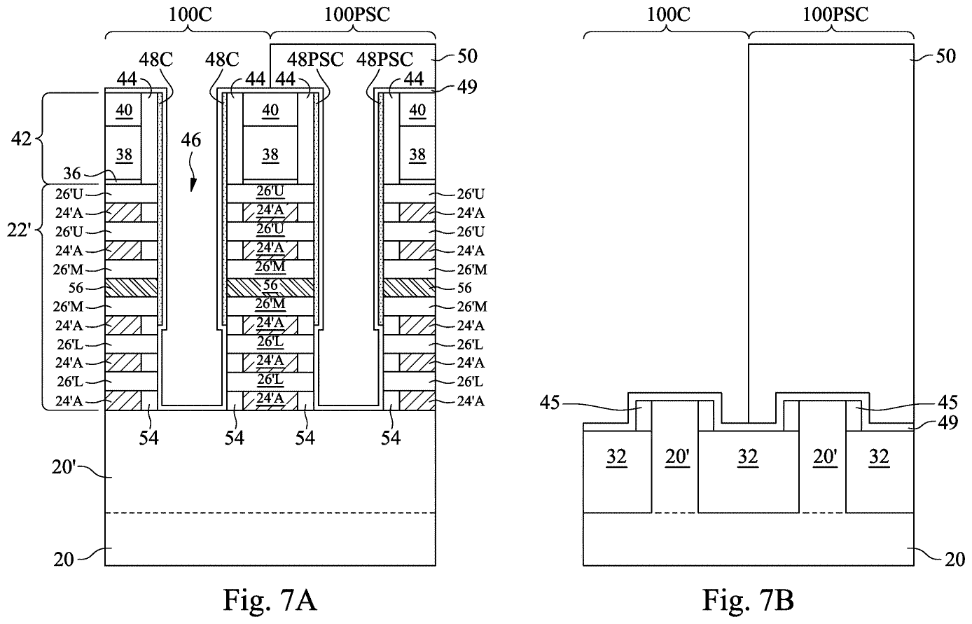

Referring to FIGS. 7A and 7B, etching mask 50 is formed and patterned. The respective process is illustrated as process 220 in the process flow 200 as shown in FIG. 16. In accordance with some embodiments, etching mask 50 may include a patterned photoresist, and may have a single-layer structure, a dual-layer structure, or a tri-layer structure. The etching mask 50 is removed from CFET region 100C, and has a remaining portion in the pseudo-CFET region 100PSC. The etching mask 50 may further fill the source/drain recess 46 in pseudo-CFET region 100PSC.

In accordance with some embodiments, the hard mask 49 and the etching mask 50 may be parts of the masks that are used for masking some protected circuit regions such as the test keys in scribe lines (not shown), so that the subsequently performed epitaxy processes will not result in the undesirable growth of semiconductor materials in the protected circuit regions. Accordingly, the formation of hard mask 49 and etching mask 50 may adopt the existing process and existing hard mask and etching mask, and will not result in extra processes. When etching mask 50 is removed from the CFET region 100C (while left in the pseudo-CFET region 100PSC), the etching mask will remain in the protected circuit regions.

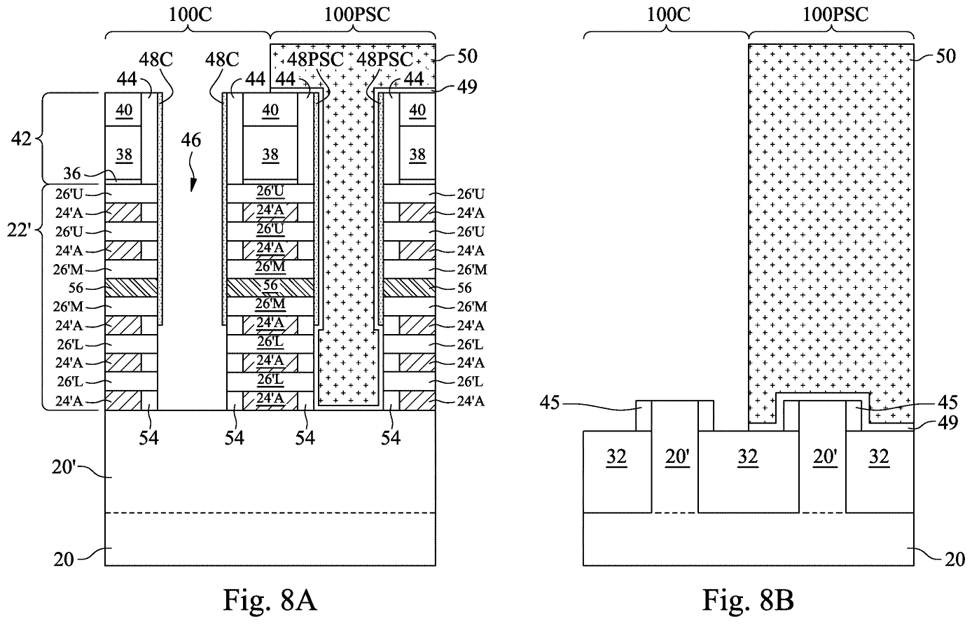

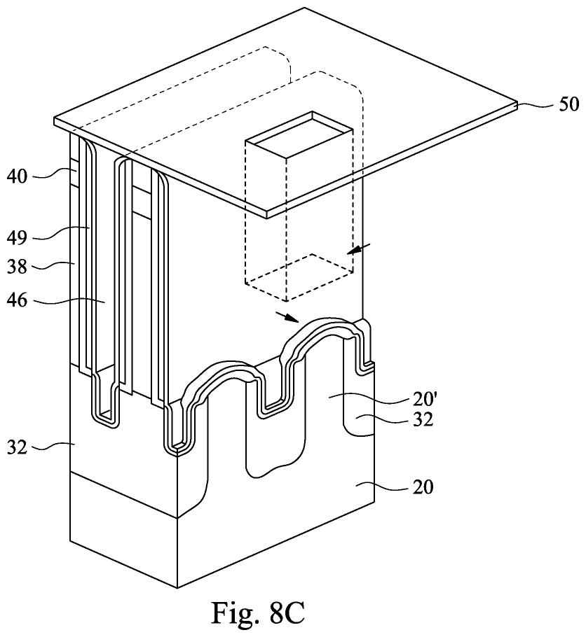

In a subsequent process, hard mask 49 is patterned in an etching process, wherein the exposed portions of the hard mask 49 are removed. The resulting structure is shown in FIGS. 8A and 8B. The respective process is illustrated as process 222 in the process flow 200 as shown in FIG. 16. The removal process may be performed through an isotropic etching process using a wet etching solution or an etching gas that attacks hard mask 49, but not protection liners 48C and 48PSC, inner spacers 54, and semiconductor strips 20′.

FIG. 8C illustrates a perspective view of the structure shown in FIGS. 8A and 8B. The illustrated portion reflects the portion in pseudo-CFET region 100PSC. Etching mask 50 is illustrated schematically. An opening in etching mask 50 schematically illustrates the CFET region 100C.

After the patterning of the hard mask 49, the remaining portions of etching mask 50 are removed, exposing the underlying hard mask 49, which is in the pseudo-CFET region 100PSC, but not in CFET region 100C.

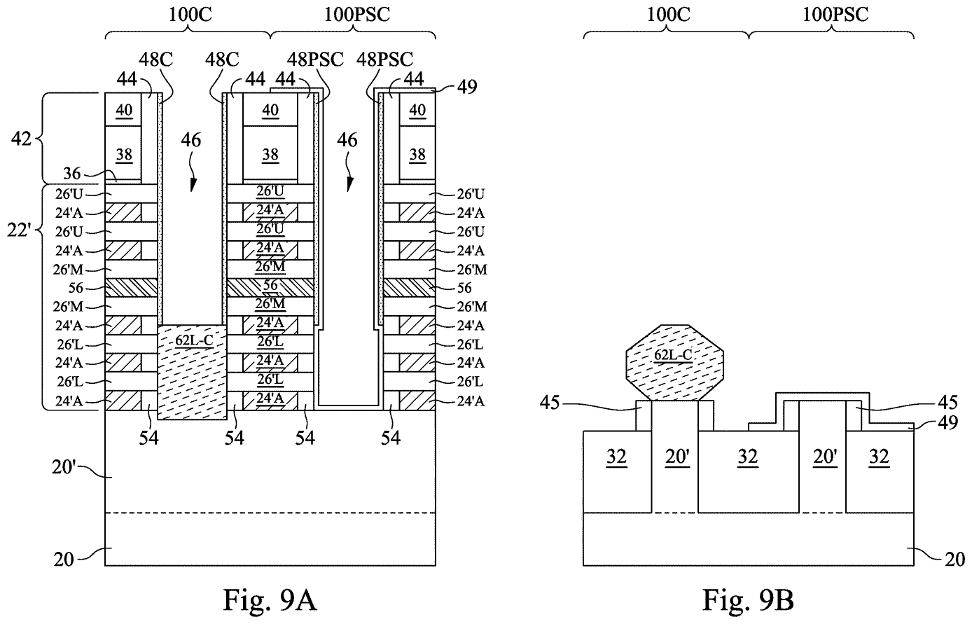

Next, as shown in FIGS. 9A and 9B, lower source/drain region 62L-C is formed in the lower portion of the source/drain recess 46 in CFET region 100C. The respective process is illustrated as process 224 in the process flow 200 as shown in FIG. 16. The lower source/drain region 62L-C is in contact with the lower semiconductor nanostructures 26′L and are not in contact with the upper semiconductor nanostructures 26′U. Inner spacers 54 physically and electrically insulate the lower source/drain regions 62L-C from the dummy nanostructures 24′A, which will be replaced with replacement gates in subsequent processes.

During the formation of lower source/drain region 62L-C, which is performed through a selective epitaxy process, due to the masking of hard mask 49, the semiconductor material is not grown in the source/drain recesses 46 in pseudo-CFET region 100PSC.

The lower source/drain region 62L-C has a conductivity type that is suitable for the device type (p-type or n-type) of the lower nanostructure-FETs. In the following discussion, it is assumed that the lower nanostructure-FETs are PFETs, and the upper nanostructure-FETs are NFETs. In accordance with alternative embodiments, the lower nanostructure-FETs may be NFETs, and the upper nanostructure-FETs may be PFETs.

When lower source/drain region 62L-C is a p-type source/drain region, the respective material may include silicon or silicon germanium, which is doped with a p-type dopant such as boron, indium, and/or the like. The lower source/drain region 62L-C may be in-situ doped, and may be, or may not be, implanted with the corresponding p-type or n-type dopants.

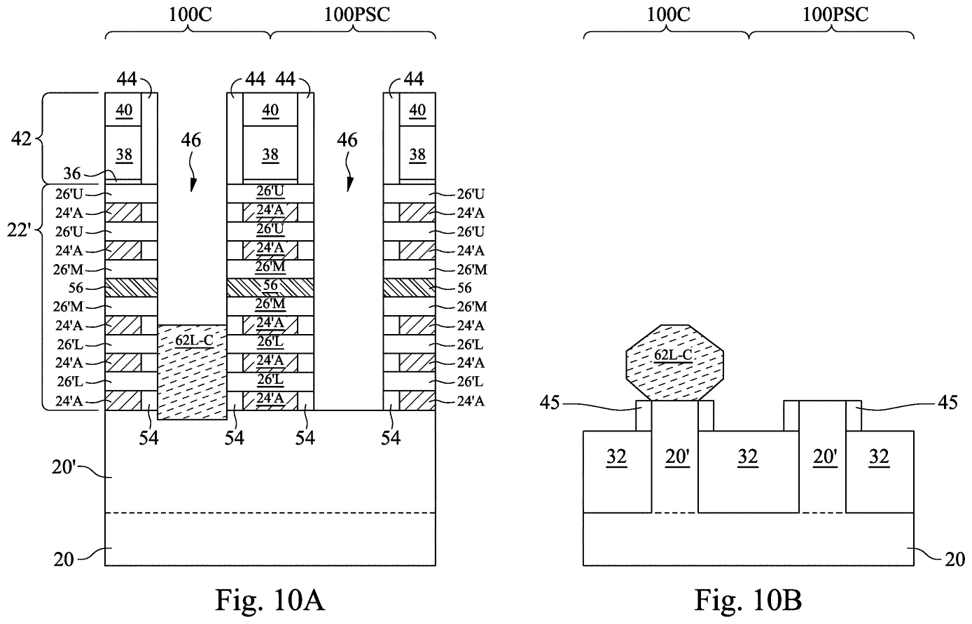

In a subsequent process, the remaining portions of the hard mask 49 are removed, and the resulting structure is shown in FIGS. 10A and 10B. The respective process is illustrated as process 226 in the process flow 200 as shown in FIG. 16. The removal process may be performed through an isotropic etching process using a wet etching solution or an etching gas that attacks hard mask 49, but not protection liners 48C and 48PSC (FIGS. 9A and 9B), inner spacers 54, lower source/drain regions 62L-C, and semiconductor strips 20′.

Next, protection liners 48C and 48PSC (FIGS. 9A and 9B) are removed. The respective process is illustrated as process 228 in the process flow 200 as shown in FIG. 16. The removal may be performed through an isotropic etching process, wherein a wet etching process or a dry etching process may be adopted. The etching chemical is selected as not to etch inner spacers 54, lower source/drain regions 62L-C, and other exposed materials such as gate spacers 44 and hard masks 40. The resulting structures are also shown in FIGS. 10A and 10B.

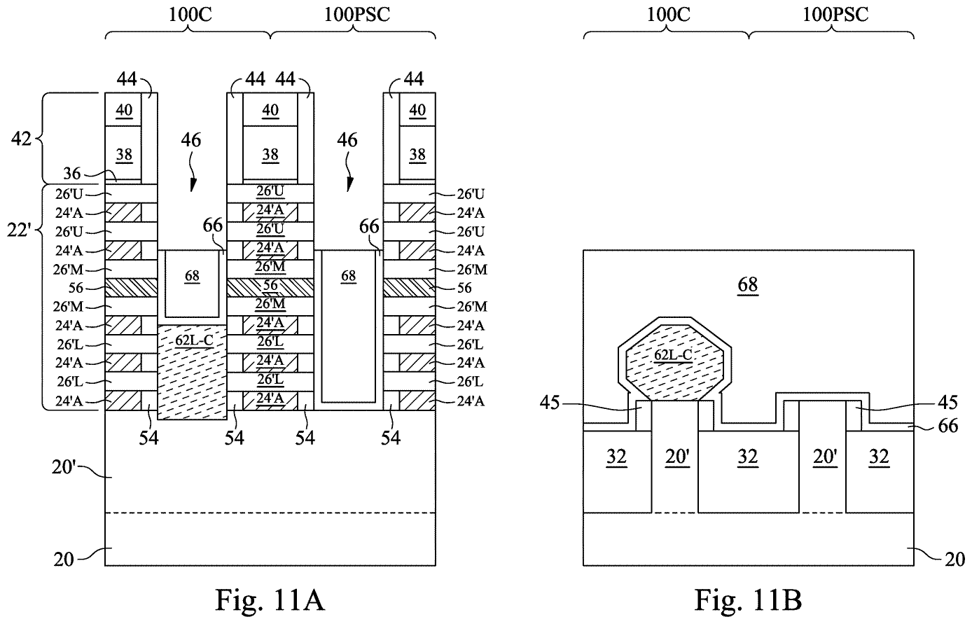

Referring to FIGS. 11A and 11B, a first contact etch stop layer (CESL) 66 and a first ILD 68 are formed. The respective process is illustrated as process 230 in the process flow 200 as shown in FIG. 16. The first CESL 66 and first ILD 68 may be formed simultaneously in CFET region 100C and pseudo-CFET region 100PSC. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process, so that the portions of the deposited materials have a planar top surface. An etch-back process is then performed to recess the deposited materials. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Due to the planarization process and the etch-back process, the top surfaces of the first ILD 68 and the first CESL 66 in CFET region 100C and pseudo-CFET region 100PSC may be at the same level, or slightly different levels. The top surfaces of the first ILD 68 and the first CESL 66 in CFET region 100C and pseudo-CFET region 100PSC, regardless of whether being at the same level or different levels, are both higher than the bottom surfaces of the inner spacers 54 that are immediately underlying dielectric isolation layers 56, and are lower than the top surfaces of the inner spacers 54 that are immediately overlying dielectric isolation layers 56.

The bottom surface of the first CESL 66 in CFET region 100C is in contact with the top surface of the lower source/drain region 62L-C. The bottom surface of the first CESL 66 in pseudo-CFET region 100PSC is lower than the bottom surface of the first CESL 66 in CFET region 100C. Furthermore, the first CESL 66 in pseudo-CFET region 100PSC is in contact with the top surface of semiconductor strip 20′ in pseudo-CFET region 100PSC, and is in contact with the sidewalls of semiconductor nanostructures 26′L.

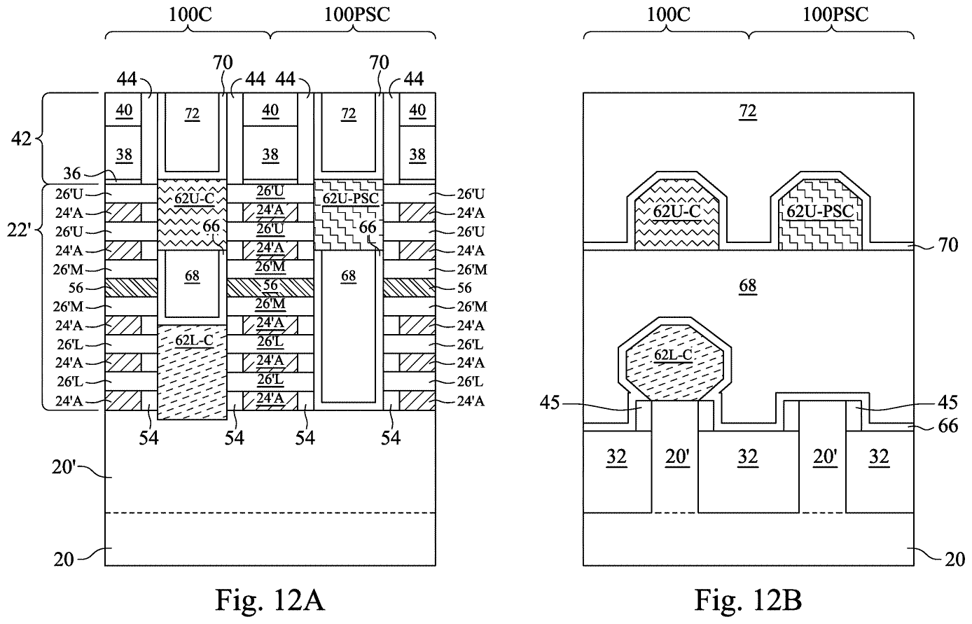

Next, referring to FIGS. 12A and 12B, upper epitaxial source/drain regions 62U-C and 62U-PSC are formed in the upper portions of the source/drain recesses 46, and are formed in CFET region 100C and pseudo-CFET region 100PSC, respectively. The respective process is illustrated as process 232 in the process flow 200 as shown in FIG. 16. Epitaxial source/drain regions 62U-C and 62U-PSC may be formed simultaneously or in separate processes. Accordingly, the upper epitaxial source/drain regions 62U-C may have the same structure and same compositions as the upper epitaxial source/drain regions 62U-PSC.

The upper epitaxial source/drain regions 62U-C and 62U-PSC may be in-situ doped, and/or may be implanted, with an n-type or p-type dopant, depending on the intended conductivity type. For example, when the upper epitaxial source/drain regions 62U-C and 62U-PSC are n-type semiconductor regions, SiP, SiCP, or the like may be adopted.

Next, a second CESL 70 and a second ILD 72 are formed. The second CESL 70 and second ILD 72 may be formed simultaneously in CFET region 100C and pseudo-CFET region 100PSC. The respective process is illustrated as process 234 in the process flow 200 as shown in FIG. 16.

The materials and the formation methods of the second CESL 70 and a second ILD 72 may be the same as or similar to the materials and the formation methods of the first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

Next, the dummy gate stacks 42 are removed in one or more etching processes, so that recesses are formed. Each of the recesses exposes and/or overlies portions of multilayer stacks 22′. The remaining portions of the dummy nanostructures 24′A (FIG. 12A) are then removed through etching, so that the recesses extend between the semiconductor nanostructures 26′U.

Replacement gate stacks 90 (each including gate stacks 90L and 90U) are then formed in the respective recesses, and may be formed in the CFET region 100C and pseudo-CFET region 100PSC simultaneously. The respective process is illustrated as process 236 in the process flow 200 as shown in FIG. 16. Gate stacks 90L include gate dielectric 78 and gate electrodes 80L. Gate stacks 90U include gate dielectrics 78 and gate electrodes 80U. Each of gate dielectrics 78 may include an interfacial layer (such as a silicon oxide layer) and a high-k dielectric layer over the interfacial layer. Gate dielectrics 78 are formed on the exposed semiconductor nanostructures 26′, and include portions on the gate spacers 44. The gate dielectrics 78 wrap around all (e.g., four) sides of the semiconductor nanostructures 26′.

Dielectric hard masks 92 are formed over the gate stacks 90U. The gate electrodes 80L and 80U include conductive materials, which may provide suitable work-functions to the resulting lower FETs (lower transistors) 10L and upper FETs (upper transistors) 10U. The gate electrodes 80L and 80U may be common gates formed in a same formation process, or may be electrically decoupled from each other.

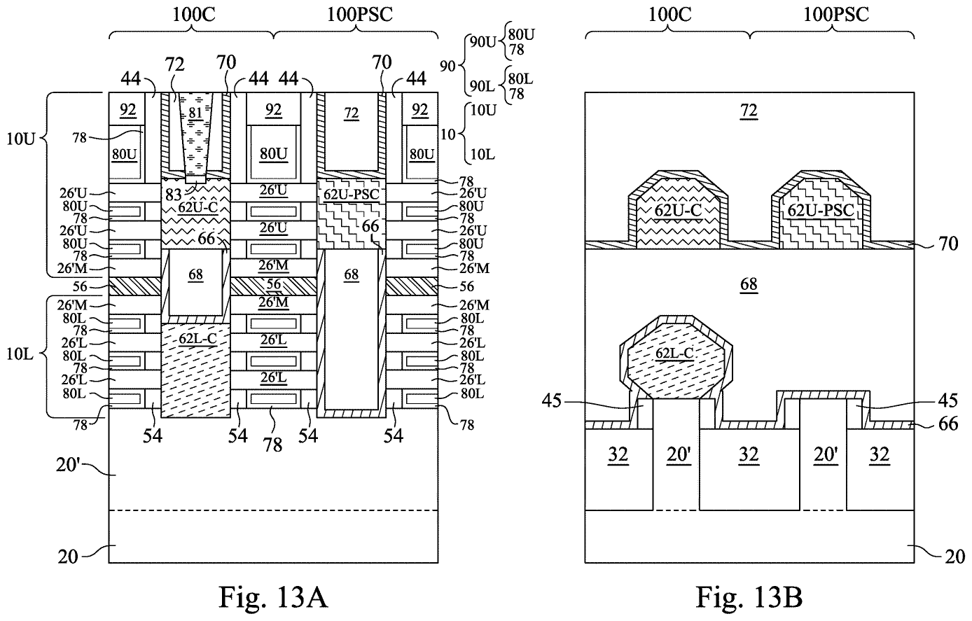

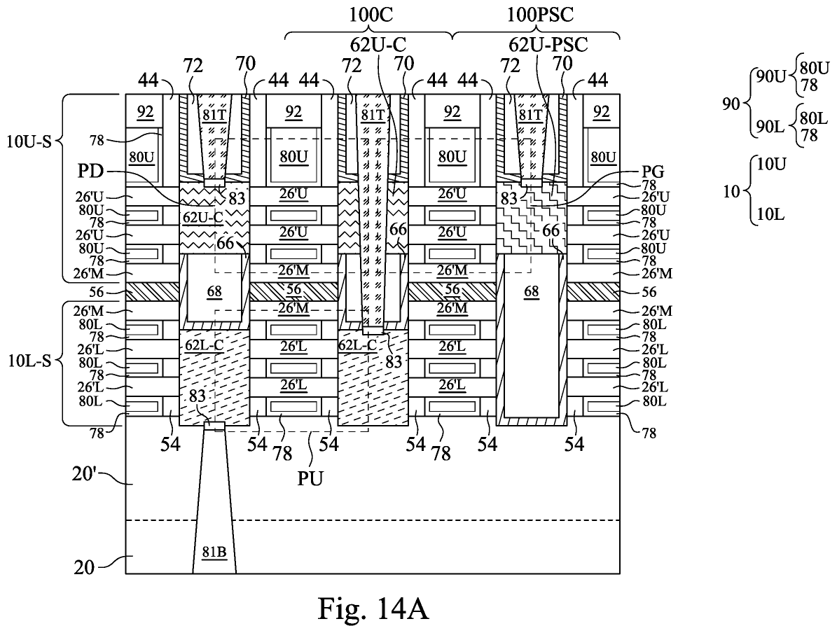

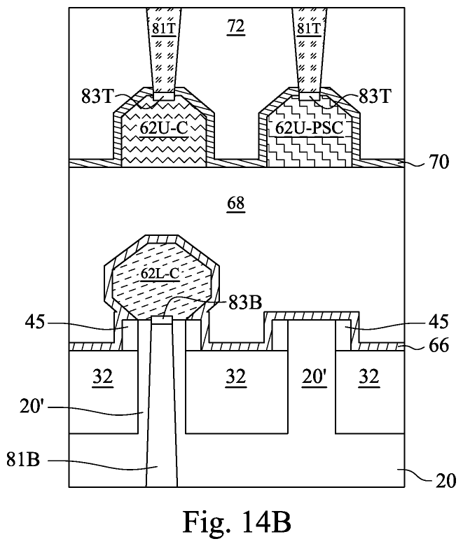

FIG. 14A illustrates a structure includes two CFET regions and a pseudo-CFET region in accordance with some embodiments. The CFET region 100C and pseudo-CFET region 100PSC as shown in FIGS. 13A and 13B may be obtained from FIG. 14A. In accordance with some embodiments, the structure shown in FIG. 14A implements a pull-up transistor PU, a pull-down transistor PD, and a pass-gate transistor PG, which transistors are also shown in FIG. 15. Accordingly, an SRAM cell 100 as shown in FIG. 15 may be implemented using the structure as shown in FIG. 14A.

FIG. 14A further illustrates the formation of top source/drain contact plugs 81 connecting to upper source/drain regions 62U-C and 62U-PSC in accordance with some embodiments, and bottom source/drain contact plugs 81B connecting to lower source/drain regions 62L-C in accordance with some embodiments. It is appreciated that the illustrated connection scheme is merely an example, and different connection schemes may be adopted. Source/drain silicide layers 83 are also formed. The electrical connection to the lower source/drain regions 62L-C may be through vertical interconnects, wherein the source/drain contact plug 81 (in the illustrated device region 100C) electrically interconnects an upper source/drain region 62U-C and a lower upper source/drain regions 62L-C.

It is appreciated that by adopting the embodiments of the present disclosure, it is not needed to form a dummy lower source/drain region, and then performing a patterning process to remove the dummy lower source/drain region for the pseudo-CFET. If the formation and the patterning are performed to remove a dummy lower source/drain region, the corresponding photolithography process may suffer from overlay shift problem, which has small process window due to the small spacing between neighboring CFETs. The uniformity of the device wafer may suffer. In addition, the removal of the dummy lower source/drain region may damage gate spacers and inner spacers.

The embodiments of the present disclosure have some advantageous features. By adopting the processes of the present disclosure, there is no need to form and then etch dummy lower source/drain regions, and the problem caused by the etching of the dummy lower source/drain regions is avoided. The processes according to the embodiments of the present disclosure may use the existing masks, and thus no extra masks and lithography process are needed.

In accordance with some embodiments of the present disclosure, a method comprises forming a first multilayer stack in a first device region; forming a first gate stack over the first multilayer stack; forming a second multilayer stack in a second device region; forming a second gate stack over the second multilayer stack; etching the first multilayer stack to form a first source/drain recess; etching the second multilayer stack to form a second source/drain recess; forming a hard mask in the second source/drain recess; forming a lower source/drain region in the first source/drain recess; after the lower source/drain region is formed, removing the hard mask from the second source/drain recess; and forming both of a first upper source/drain region in the first source/drain recess and a second upper source/drain region in the second source/drain recess, respectively.

In an embodiment, the lower source/drain region is of a first conductivity type, and wherein the first upper source/drain region and the second upper source/drain region are of a second conductivity type opposite to the first conductivity type. In an embodiment, the first conductivity type is p-type, and the second conductivity type is n-type. In an embodiment, the first upper source/drain region, the lower source/drain region, and the second upper source/drain region are formed as parts of a pull-up transistors, a pull-down transistor, and a pass-gate transistor, respectively, of a static random-access memory cell.

In an embodiment, the method further comprises, after the hard mask is removed from the second source/drain recess, forming a contact etch stop layer and an inter-layer dielectric over the contact etch stop layer, wherein parts of the contact etch stop layer and the inter-layer dielectric are in the second source/drain recess and at a same level as the lower source/drain region. In an embodiment, the contact etch stop layer is in contact with semiconductor nanostructures of the second multilayer stack. In an embodiment, the parts of the contact etch stop layer extend to a bottom of the second source/drain recess.

In an embodiment, the forming the hard mask comprises depositing a blanket hard mask layer into the first device region and the second device region; and removing the blanket hard mask layer from the first device region. In an embodiment, the method further comprises, before the blanket hard mask layer is deposited, forming a first protection liner and a second protection liner in upper parts of the first source/drain recess and the second source/drain recess, respectively. In an embodiment, the method further comprises replacing the first gate stack with a first replacement gate stack; and replacing the second gate stack with a second replacement gate stack. In an embodiment, the first replacement gate stack and the second replacement gate stack are formed sharing common processes.

In accordance with some embodiments of the present disclosure, a method comprises forming a first source/drain recess in a first device region, wherein the first source/drain recess is between first two neighboring multilayer stacks, and wherein a first top surface of a first semiconductor region is underlying and exposed to the first source/drain recess; forming a second source/drain recess in a second device region, wherein the second source/drain recess is between second two neighboring multilayer stacks, and wherein a second top surface of a second semiconductor region is underlying and exposed to the second source/drain recess; forming a hard mask in the second source/drain recess and on surfaces of the second two neighboring multilayer stacks; forming a lower source/drain region in the first source/drain recess; removing the hard mask; and forming a first contact etch stop layer comprising a first portion in the first source/drain recess, wherein the first portion contacts a third top surface of the lower source/drain region; and a second portion in the second source/drain recess, wherein the second portion contacts the second top surface of the second semiconductor region.

In an embodiment, the method further comprises forming a first inter-layer dielectric over the first contact etch stop layer, wherein the first inter-layer dielectric comprises portions in the first source/drain recess and the second source/drain recess, respectively. In an embodiment, the method further comprises forming a first upper source/drain region in the first source/drain recess; and a second upper source/drain region in the second source/drain recess. In an embodiment, the first source/drain recess and the second source/drain recess are formed in a common process.

In an embodiment, the method further comprises forming a second contact etch stop layer comprising parts in the first source/drain recess and the second source/drain recess. In an embodiment, the first upper source/drain region, the lower source/drain region, and the second upper source/drain region are formed as parts of a static random-access memory cell.

In accordance with some embodiments of the present disclosure, a structure comprises a first device comprising a first plurality of semiconductor nanostructures comprising a first semiconductor nanostructure, and a second semiconductor nanostructure overlapping the first semiconductor nanostructure; a lower source/drain region laterally adjoining the first semiconductor nanostructure; and a first upper source/drain region overlapping the lower source/drain region, wherein the first upper source/drain region contacts the second semiconductor nanostructure; a first dielectric region between the lower source/drain region and the first upper source/drain region; a second device comprising a second plurality of semiconductor nanostructures comprising a third semiconductor nanostructure, and a fourth semiconductor nanostructure overlapping the third semiconductor nanostructure; and a second upper source/drain region laterally adjoining the fourth semiconductor nanostructure; and a second dielectric region under the second upper source/drain region, wherein the second dielectric region laterally adjoins the third semiconductor nanostructure.

In an embodiment, the second dielectric region comprises a contact etch stop layer and an inter-layer dielectric over the contact etch stop layer. In an embodiment, the structure further comprises a semiconductor strip, wherein the second dielectric region contacts a top surface of the semiconductor strip.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first multilayer stack over a first semiconductor strip;
forming a first gate stack over the first multilayer stack;
forming a second multilayer stack over a second semiconductor strip;
forming a second gate stack over the second multilayer stack;
etching the first multilayer stack to form a first source/drain recess;
etching the second multilayer stack to form a second source/drain recess;
forming a lower source/drain region in the first source/drain recess, wherein when the lower source/drain region is formed, the second source/drain recess is prevented from having a source/drain region formed therein; and
simultaneously forming a first upper source/drain region in the first source/drain recess and a second upper source/drain region in the second source/drain recess.

2. The method of claim 1, wherein opposing sidewalls of the first semiconductor strip and the second semiconductor strip are in contact with sidewalls of shallow trench isolation regions.

3. The method of claim 1, wherein at a time after the lower source/drain region is formed in the first source/drain recess, a top surface of the second semiconductor strip is underlying and exposed to the second source/drain recess.

4. The method of claim 1 further comprising:
forming a first contact etch stop layer in the first source/drain recess, with a first bottom surface of the first contact etch stop layer contacting the lower source/drain region; and
forming a second contact etch stop layer in the second source/drain recess, with a second bottom surface of the second contact etch stop layer contacting the second semiconductor strip.

5. The method of claim 1, wherein the lower source/drain region is of a first conductivity type, and wherein the first upper source/drain region and the second upper source/drain region are of a second conductivity type opposite to the first conductivity type.

6. The method of claim 5, wherein the first conductivity type is p-type, and the second conductivity type is n-type.

7. The method of claim 1, wherein the first upper source/drain region, the lower source/drain region, and the second upper source/drain region are formed as parts of a pull-down transistors, a pull-up transistor, and a pass-gate transistor, respectively, of a static random-access memory cell.

8. The method of claim 1 further comprising:
forming a hard mask in the second source/drain recess, wherein the lower source/drain region is formed when the hard mask is in the second source/drain recess; and
after the lower source/drain region is formed, removing the hard mask.

9. The method of claim 1 further comprising forming a contact etch stop layer and an inter-layer dielectric over the contact etch stop layer, wherein parts of the contact etch stop layer and the inter-layer dielectric are in the second source/drain recess and at a same level as the lower source/drain region.

10. The method of claim 9, wherein a part of the contact etch stop layer in the second source/drain recess is in contact with a semiconductor nanostructure of the second multilayer stack.

11. A method comprising:
forming a first multilayer stack comprising:
a first lower semiconductor nanostructure;
a first dielectric isolation layer over the first lower semiconductor nanostructure; and
a first upper semiconductor nanostructure over the first dielectric isolation layer;
forming a second multilayer stack comprising:
a second lower semiconductor nanostructure;
a second dielectric isolation layer over the second lower semiconductor nanostructure; and
a second upper semiconductor nanostructure over the second dielectric isolation layer;
etching the first multilayer stack to form a first source/drain recess;
etching the second multilayer stack to form a second source/drain recess;
forming a lower source/drain region electrically joined to the first lower semiconductor nanostructure; and
forming a contact etch stop layer comprising:
a first portion in the first source/drain recess; and
a second portion in the second source/drain recess, wherein the second portion extends to a level lower than the second lower semiconductor nanostructure.

12. The method of claim 11, wherein the second portion of the contact etch stop layer extends to the level that is also lower than a bottommost surface of the second multilayer stack.

13. The method of claim 11 further comprising simultaneously forming a first upper source/drain region and a second upper source/drain region in the first source/drain recess and the second source/drain recess, respectively.

14. The method of claim 11, wherein the second portion of the contact etch stop layer physically contacts a sidewall of the second lower semiconductor nanostructure.

15. The method of claim 11 further comprising forming a hard mask, wherein when the lower source/drain region is formed, the hard mask is a liner lining the second source/drain recess.

16. The method of claim 15, wherein the forming the hard mask comprises:
depositing a blanket hard mask layer into the first source/drain recess and the second source/drain recess; and
removing the blanket hard mask layer from the first source/drain recess.

17. The method of claim 16 further comprising, before the blanket hard mask layer is deposited, forming a first protection liner and a second protection liner in upper parts of the first source/drain recess and the second source/drain recess, respectively.

18. A method comprising:
forming a first multilayer stack and a second multilayer stack;
forming a first gate stack and a second gate stack over the first multilayer stack and the second multilayer stack, respectively;
etching the first multilayer stack and the second multilayer stack to form a first source/drain recess and a second source/drain recess, respectively;
forming a first dielectric liner and a second dielectric liner lining upper portions of the first source/drain recess and the second source/drain recess, respectively;
forming a hard mask, wherein a first semiconductor nanostructure of the first multilayer stack is exposed to a lower portion of the first source/drain recess, and a second semiconductor nanostructure of the second multilayer stack contacts the hard mask;
performing a selective growth to form a lower source/drain region in the first source/drain recess;
removing the hard mask; and
simultaneously forming a first upper source/drain region and a second upper source/drain region in the first source/drain recess and the second source/drain recess, respectively.

19. The method of claim 18 further comprising:
forming a first contact etch stop layer over the lower source/drain region; and
forming a second contact etch stop layer contacting the second semiconductor nanostructure of the second multilayer stack.

20. The method of claim 18 further comprising, before the first upper source/drain region and the second upper source/drain region are formed, removing the first dielectric liner and the second dielectric liner.
